(19) United States
(12) Patent Application Publication
(10) Pub. No.: US 2007/0089013 A1
(43) Pub. Date: Apr. 19, 2007

(54) SYSTEM AND METHOD FOR TESTING PORTS OF A COMPUTER

(75) Inventors: Li-Chuan Qiu, Shenzhen (CN); Hoi Chan, Shenzhen (CN); Qing-Long Chai, Shenzhen (CN); Xiao-Ming Xu, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/309,339

(22) Filed: Jul. 28, 2006

(30) Foreign Application Priority Data
Sep. 9, 2005 (CN) 200510037231.0

(51) Int. Cl. G01R 31/28; G06F 11/00

(52) U.S. Cl. 714/742

(57) ABSTRACT

The present invention provides a method for testing ports of a computer. The method includes steps of: connecting the testing ports and the non-testing ports of the computer according to a configuration document; creating virtual devices corresponding to the non-testing ports; analyzing corresponding relations between the virtual devices, the non-testing ports, and the testing ports; analyzing a count of the testing ports; and determining whether the testing ports are in good working condition by determining whether the count of the testing ports is equal to a count of the configuration records. A related system is also disclosed.

### DESCRIPTION

1. Field of the Invention

The present invention relates to a system and method for testing ports of a computer.

2. Description of Related Art

A typical computer has many different kinds of ports therein (e.g., FireWire ports, USB ports etc), these ports being configured for connecting the computer with peripheral devices, such as a digital vidicon (DV), a digital camera, a hard disk, and so on. FireWire ports are high-speed serial buses designed for strengthening connectivity between computers and multimedia devices. The transmitting speed of the FireWire ports can reach about 400 Mbps. It is easy to connect the computer with the peripheral devices for transmitting data quickly by using the FireWire ports. Furthermore, the FireWire ports can support as many as 63 peripheral devices running simultaneously on the computer and can support PNP (Plug and Play) technologies.

The FireWire ports of a computer need to be tested before being put into market. Generally, computer manufacturers utilize peripheral devices to test the FireWire ports. When a mass of FireWire ports of computers need to be tested, the peripheral devices are prone to be destroyed easily, resulting in testing costs increase and testing efficiency affected significantly.

What is needed, therefore, is a system and method that can test various ports of the computer without utilizing any peripheral devices, and can improve the testing efficiencies.

### SUMMARY OF THE INVENTION

A system for testing ports of a computer is provided. The system includes a configuration document, a detecting module, a creating module, and a determining module. The configuration document is configured for providing a guide on how to connect testing ports and non-testing ports of the computer, wherein the configuration document comprises a plurality of configuration records for assisting to determine whether the testing ports are in good working condition. The detecting module is configured for connecting the testing ports and the non-testing ports according to the configuration document, and for detecting a count of the testing ports. The creating module is configured for creating the virtual devices corresponding to the non-testing ports. The determining module is configured for analyzing corresponding relations between the virtual devices, the non-testing ports, and the testing ports, and for determining whether the testing ports are in good working condition by determining whether the count of the testing ports is equal to a count of the configuration records.

Furthermore, a method for testing ports of a computer is provided. The method includes the steps of: connecting the testing ports and the non-testing ports of the computer according to a configuration document; creating virtual devices corresponding to the non-testing ports; analyzing corresponding relations between the virtual devices, the non-testing ports, and the testing ports; analyzing a count of the testing ports; and determining whether the testing ports are in good working condition by determining whether the count of the testing ports is equal to a count of the configuration records.

Moreover, another method for creating a configuration document is provided. The method includes the steps of: connecting testing ports and non-testing ports of a working specimen of the computer; creating virtual devices corresponding to the non-testing ports; analyzing corresponding relations between the virtual devices, the non-testing ports, and the testing ports; creating configuration records comprising the corresponding relations; and inputting the configuration records into the configuration document.

Other advantages and novel features of the present invention will become more apparent from the following detailed description of preferred embodiments when taken in conjunction with the accompanying drawings.

### BRIEF DESCRIPTION OF THE DRAWINGS

FIG. 1 is a schematic diagram of a hardware configuration of a system for testing ports of a computer in accordance with a preferred embodiment;

FIG. 2 is a schematic diagram of main software function modules of the system of FIG. 1;

FIG. 3 is a flowchart of a method for creating a configuration document; and

FIG. 4 is a flowchart of a method for testing ports of a computer in accordance with a preferred embodiment.

### DETAILED DESCRIPTION OF THE INVENTION

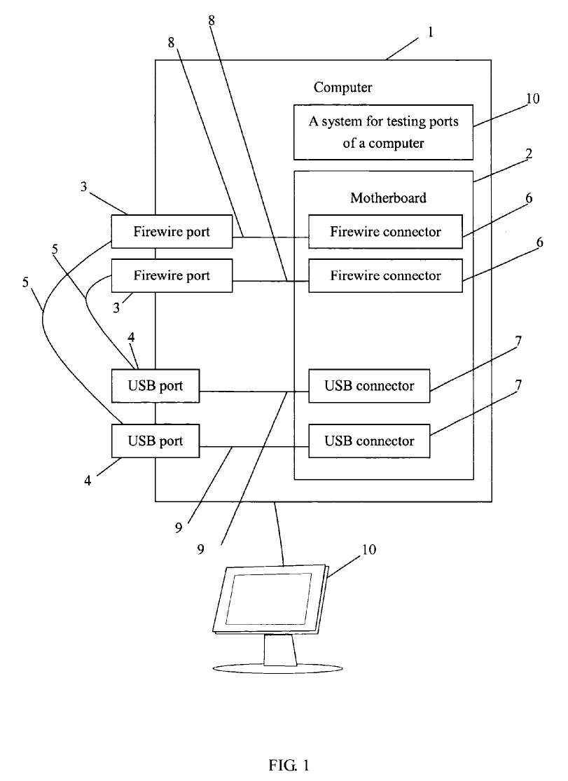

FIG. 1 is a schematic diagram of a hardware configuration of a system for testing ports of a computer (hereinafter, “the system”) in accordance with a preferred embodiment. The system 10 is installed in a computer 1. The computer 1 includes a motherboard 2 and various ports, such as FireWire ports 3 and universal serial bus (USB) ports 4. These ports correspond to connectors on the motherboard 2, such as FireWire connectors 6 and USB connectors 7. The FireWire connectors 6 are connected with the FireWire ports 3 via FireWire extension cables 9 correspondingly, and the USB connectors 7 are connected with the USB ports 4 via USB cables 8 correspondingly. The FireWire ports 3 are connected with the USB ports 4 via FireWire to USB cables 5 correspondingly. The computer 1 connects with a display 10 that is configured for displaying a testing process, various data created in the testing process, and test results etc.

In this embodiment, testing ports are FireWire ports 3 and non-testing ports are USB ports 4. Alternatively, the testing ports and the non-testing ports can also be other kinds of ports.

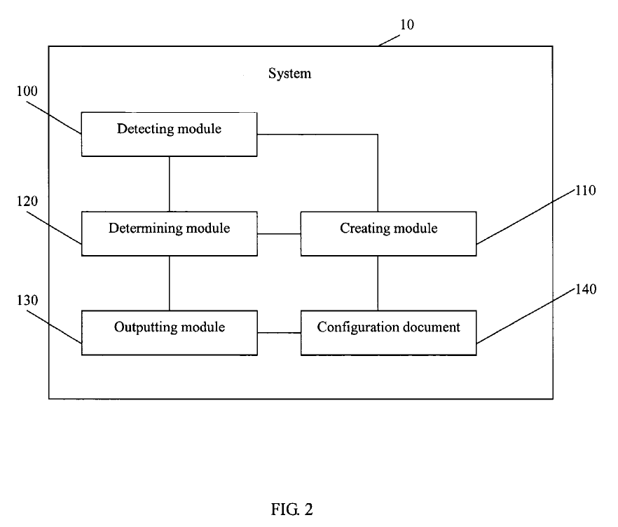

FIG. 2 is a schematic diagram of main software function modules of the system 10. The system 10 includes a detecting module 100, a creating module 110, a determining module 120, an outputting module 130, and a configuration document 140.

Before testing, a working specimen of computer 1 is selected for creating the configuration document 140 to be used in testing computers 1 having the same specifications. The configuration document 140 is configured for providing a guide on how to connect the FireWire ports 3 and the USB ports 4 of the computer 1 for a tester. The configuration document 140 includes a plurality of configuration records for assisting to determine whether the FireWire ports 3 of the computer 1 are in good working condition.

The detecting module 100 is configured for detecting a count of the FireWire ports 3 of the working specimen and prompting the tester to connect the FireWire ports 3 with the USB ports 4 via the FireWire to USB cables 5 correspondingly.

The creating module 110 is configured for creating virtual USB devices simulating peripheral devices corresponding to the USB ports 4 of the working specimen. In other embodiments, the virtual USB devices can be other kinds of virtual devices according to a type of the non-testing ports.

The determining module 120 is configured for analyzing corresponding relations between the virtual devices, the non-testing ports, and the testing ports. Each virtual USB device corresponds to one of the USB ports 4, and each USB port 4 corresponds to one of the FireWire ports 3. For example, the creating module 110 creates three virtual USB devices, the determining module 120 analyzes the first virtual USB device that corresponds to the first USB port 4, and analyzes the first USB port 4 that corresponds to the first FireWire port 3.

The creating module 110 is also configured for creating configuration records including the corresponding relations between the virtual devices, the non-testing ports, and the testing ports, and for inputting the configuration records into the configuration document 140. A count of the configuration records is equal to the count of the FireWire ports 3.

The outputting module 130 is configured for outputting the configuration document 140.

During the testing process, the tester connects the FireWire ports 3 and the USB ports 4 of the computers 1 to be tested according to the configuration document 140. The creating module 110 is configured for creating the virtual USB devices corresponding to the USB ports 4 of the computers 1 to be tested. The detecting module 100 is configured for detecting the count of the FireWire ports 3 of the computer 1. The determining module 120 is configured for analyzing corresponding relations between the virtual USB devices, the USB ports 4, and the FireWire ports 3, and for determining whether the FireWire ports 3 are in good working condition by determining whether the count of the FireWire ports 3 is equal to a count of the configuration records.

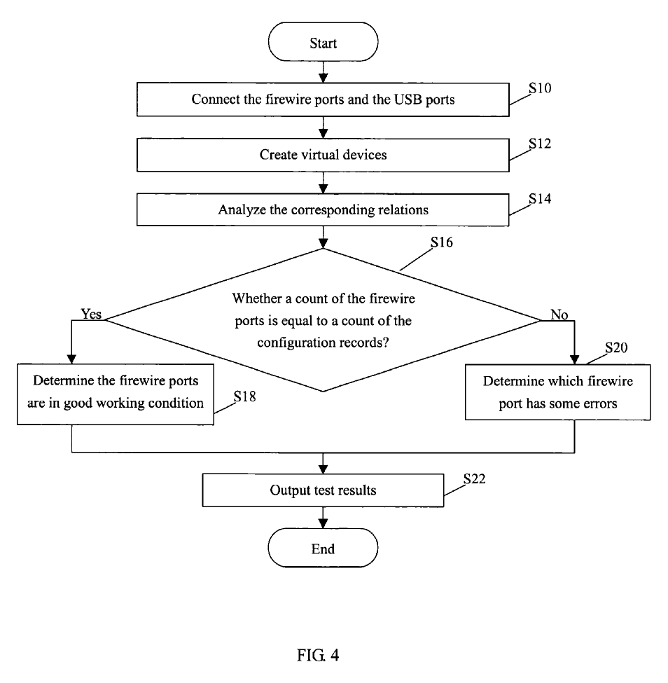

If the count of the testing ports is equal to the count of the configuration records, the determining module 120 is configured for determining that the testing ports are in good working condition and the connections between the FireWire ports 3 and the FireWire connectors 6 are good; otherwise, if the count of the testing ports is not equal to the count of the configuration records, the determining module 120 is further configured for determining which testing ports have errors according to comparing the corresponding relations with the configuration records (described in detail below in relation to FIG. 4).

The outputting module 130 is configured for outputting the configuration document 140 and test results that analyzed by the determining module 120. The test results include contents of which FireWire ports 3 are good and which FireWire ports 3 have errors. The outputting module 130 is further configured for displaying the test results on the display 10.

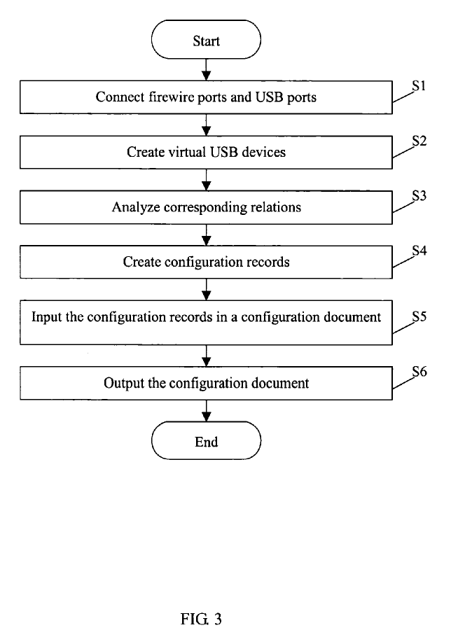

FIG. 3 is a flowchart of a method for creating a configuration document. In step S1, the working specimen of computer 1 having the same specification is selected, and the detecting module 100 detects the count of the FireWire ports 3 of the working specimen and prompts the tester to connect one FireWire port 3 with one USB port 4 with the FireWire to USB cable 5 correspondingly.

In step S2, the creating module 110 creates the virtual USB devices corresponding to the USB ports 4. In step S3, the determining module 120 analyzes the corresponding relations between the virtual devices, the USB ports 4, and the FireWire ports respectively.

In step S4, the creating module 110 creates the configuration records including the corresponding relations, the count of the configuration records is equal to the count of the FireWire ports 3 of the working specimen. In step S5, the creating module 110 inputs all the configuration records into the configuration document 140. In step S6, the outputting module 130 outputs the configuration document 140, which guides the tester how to test the computers 1, and the testing process is described in detail as FIG. 4.

FIG. 4 is a flowchart of a method for testing ports of a computer. In step S10, the tester connects the FireWire ports 3 with the USB ports 4 of one of the computers 1 according to the configuration records in the configuration document 140. In step S12, the creating module 110 creates a plurality of virtual USB devices corresponding to the USB ports 4.

In step S14, the determining module 120 analyzes corresponding relations between the virtual devices, the non-testing ports, and the testing ports respectively.

In step S16, the determining module 120 determines whether the count of the FireWire ports 3 of the computer 1 is equal to the count of the configuration records. If the count of the FireWire ports 3 is equal to the count of the configuration records, in step S18, the determining module 120 determines the FireWire ports 3 of the computer 1 are in good working condition, and the connections between the FireWire ports 3 and the respective FireWire connectors 6 are good.

Otherwise, in step S20, if the count of the FireWire ports 3 is not equal to the count of the configuration records, the determining module 120 determines which FireWire ports 3 have errors according to comparing the corresponding relations with the configuration records. The errors include an error of the FireWire port 3 and an error of a connection between the FireWire port 3 and the FireWire connector 6.

For example, if the count of the configuration records is three, and the count of FireWire ports 3 of the computer is analyzed as two in step S14. In the configuration records, the first USB port 4 corresponds to the first FireWire port 3, the second USB port 4 corresponds to the second FireWire port 3, and the third USB port 4 corresponds to the third FireWire port 3. The corresponding relations analyzed in step S14 show the result the first USB port 4 corresponds to the first FireWire port 3 and the second USB port 4 corresponds to the second FireWire port 3. Then the determining module 120 determines the third FireWire port 3 has errors.

In step S22, the outputting module 130 outputs the test results and displays the test results on the display 10, the test results includes a result of which FireWire ports 3 are good and a result of which FireWire port 3 have errors. The tester may find out whether a corresponding FireWire port 3 is in error or whether the connection between the FireWire port 3 and the FireWire connector 6 is in error according to the test results.

It should be emphasized that the above-described embodiments, particularly, any “preferred” embodiments, are merely possible examples of implementations, merely set forth for a clear understanding of the principles of the invention. Many variations and modifications may be made to the above-described preferred embodiment(s) without departing substantially from the spirit and principles of the invention. All such modifications and variations are intended to be included herein within the scope of this disclosure and the above-described preferred embodiment(s) and protected by the following claims.

What is claimed is:

1. A system for testing ports of a computer, the system comprising:
a configuration document configured for providing a guide on how to connect testing ports and non-testing ports of the computer, wherein the configuration document comprises a plurality of configuration records for assisting to determine whether the testing ports are in good working condition;
a detecting module configured for connecting the testing ports and the non-testing ports according to the configuration document, and for detecting a count of the testing ports;
a creating module configured for creating the virtual devices corresponding to the non-testing ports; and
a determining module configured for analyzing corresponding relations between the virtual devices, the non-testing ports, and the testing ports, and for determining whether the testing ports are in good working condition by determining whether the count of the testing ports is equal to a count of the configuration records.

2. The system as claimed in claim 1, wherein the determining module is further configured for determining the testing ports are in good working condition if the count of the testing ports is equal to the count of the configuration records.

3. The system as claimed in claim 1, wherein the determining module is further configured for determining which testing ports have errors if the count of the testing ports is not equal to the count of the configuration records.

4. The system as claimed in claim 1, further comprising an outputting module configured for outputting the configuration document.

5. The system as claimed in claim 1, wherein the testing ports are FireWire ports, and the non-testing ports are universal serial bus ports.

6. A method for testing ports of a computer, the method comprising the steps of:
connecting the testing ports and the non-testing ports of the computer according to a configuration document;
creating virtual devices corresponding to the non-testing ports;
analyzing corresponding relations between the virtual devices, the non-testing ports, and the testing ports;
analyzing a count of the testing ports; and
determining whether the testing ports are in good working condition by determining whether the count of the testing ports is equal to a count of the configuration records.

7. The method according to claim 6, wherein the configuration document is created by the steps of:
connecting testing ports and non-testing ports of a working specimen of the computer;
creating virtual devices corresponding to the non-testing ports of the working specimen;
analyzing corresponding relations between the virtual devices, the non-testing ports, and the testing ports;
creating configuration records comprising the corresponding relations; and
inputting the configuration records into the configuration document.

8. The method according to claim 6, further comprising the steps of:
determining the testing ports are in good working condition if the count of the testing ports is equal to the count of the configuration records; and
determining which testing ports have errors according to the configuration records, if the count of the testing ports is not equal to the count of the configuration records.

9. The method according to claim 6, further comprising the step of outputting the configuration document.

10. The method according to claim 6, wherein the testing ports are FireWire ports, and the non-testing ports are universal serial bus ports.

11. A method for creating a configuration document, the method comprising the steps of:
connecting testing ports and non-testing ports of a working specimen of the computer;
creating virtual devices corresponding to the non-testing ports;
analyzing corresponding relations between the virtual devices, the non-testing ports, and the testing ports;
creating configuration records comprising the corresponding relations; and
inputting the configuration records into the configuration document.
